(19) United States
(12) Patent Application Publication
(10) Pub. No.: US 2017/0229590 A1
(43) Pub. Date: Aug. 10, 2017

(54) POWER GENERATION BATTERY

(71) Applicant: Honda Motor Co.,Ltd., Tokyo (JP)

(72) Inventors: Koji OKABE, Saitama (JP); Takashi KONDO, Saitama (JP); Masaki KAWAMURA, Saitama (JP)

(73) Assignee: Honda Motor Co.,Ltd., Tokyo (JP)

(21) Appl. No.: 15/426,044

(22) Filed: Feb. 6, 2017

(30) Foreign Application Priority Data
Feb. 8, 2016 (JP) 2016-021916

(51) Int. Cl. H01L 31/0216; H01L 31/0224

(52) U.S. Cl. CPC H01L 31/02164; H01L 31/022425; H01L 31/022475

(57) ABSTRACT

Provided is a power generation battery capable of improving power generation efficiency. The power generation battery includes a first layer, a second layer, and a filter layer. The first layer includes a semiconductor element that has a main absorption region in a visible light region and absorbs a light to generate electric power. The second layer, disposed on a side opposite to an incident direction side of the first layer, includes a semiconductor element that has a main absorption region in an infrared light region and absorbs light to generate electric power. The filter layer is disposed between the first layer and the second layer and blocks or absorbs a light in the visible light region.

### CROSS-REFERENCE TO RELATED APPLICATION

This application claims the priority benefit of Japan application serial no. 2016-021916, filed on Feb. 8, 2016. The entirety of the above-mentioned patent application is hereby incorporated by reference herein and made a part of this specification.

### BACKGROUND OF THE INVENTION

Field of the Invention

The invention relates to a power generation battery.

Description of Related Art

The conventional power generation battery has a configuration that an infrared light photoelectric conversion layer and a visible light photoelectric conversion layer are laminated in this order from the, incident direction side and the two photoelectric conversion layers are interposed between two electrodes, wherein the infrared light photoelectric conversion layer has a light absorption peak in the infrared light region while the visible light photoelectric conversion layer has a light absorption peak in the visible light region (refer to Patent Literature 1, for example).

### PRIOR ART LITERATURE

### Patent Literature

Patent Literature 1: Japanese Patent Publication No. 2009-60051

### SUMMARY OF THE INVENTION

### Problem to be Solved

According to the conventional technology, however, when the light incident from the side of the infrared light photoelectric conversion layer reaches the visible light photoelectric conversion layer, the intensity of the incident light in the visible light region may be attenuated. For this reason, the power generation may not be performed efficiently. In view of the above, the invention provides a power generation battery that is capable of improving the efficiency of power generation.

### Solution to the Problem

According to an embodiment of the invention, a power generation battery 1, 1A includes: a first layer 14 which includes a semiconductor element that has a main absorption region in a visible light region and absorbs a light to generate electric power; a second layer 32 which is disposed on a side opposite to an incident direction side of the first layer, and includes a semiconductor element that has a main absorption region in an infrared light region and absorbs light to generate electric power; and a filter layer 30, 20, 20A that is disposed between the first layer and the second layer and blocks or absorbs a light in the visible light region.

According to an embodiment of the invention, the aforementioned power generation battery further includes an intermediate layer 20 between the first layer and the second layer, in addition to the filter layer, wherein the intermediate layer includes an electrode that conducts with the first layer and an electrode that conducts with the second layer.

According to an embodiment of the invention, the aforementioned power generation battery further includes an intermediate layer 20A between the first layer and the second layer, in addition to the filter layer, wherein the intermediate layer combines electrons supplied from one of the first layer and the second layer with holes supplied from the other one of the first layer and the second layer.

According to an embodiment of the invention, in the aforementioned power generation battery, the filter layer is an intermediate layer which blocks or absorbs light in the visible light region and includes an first electrode that conducts with the first layer and an second electrode that conducts with the second layer, or an intermediate layer which blocks or absorbs light in the visible light region and combines electrons supplied from one of the first layer and the second layer with holes supplied from the other one of the first layer and the second layer.

### BRIEF DESCRIPTION OF THE DRAWINGS

FIG. 1 is a diagram showing an example of the configuration of the power generation battery 1.

FIG. 2 is a diagram for illustrating the wavelengths absorbed by the first photoelectric conversion layer 14 and the second photoelectric conversion layer 32.

FIG. 3 is a diagram for illustrating the apex of light absorption and the integrated value of absorbance.

FIG. 4 is a diagram showing an example where lamination of the visible light cut filter 30 is omitted.

FIG. 5 is a diagram showing an example of the configuration of the power generation battery 1A.

FIG. 6 is a diagram showing an example where lamination of the visible light cut filter 30 is omitted.

FIG. 7 illustrates an example of the vehicle M, which utilizes the power generation battery module 100 configured by arranging a plurality of the power generation batteries 1 and 1A.

FIG. 8 is a diagram showing an example of the vehicle M1, in which the power generation battery module 100 is disposed in place of the rear window of the vehicle M1.

### DESCRIPTION OF THE EMBODIMENTS

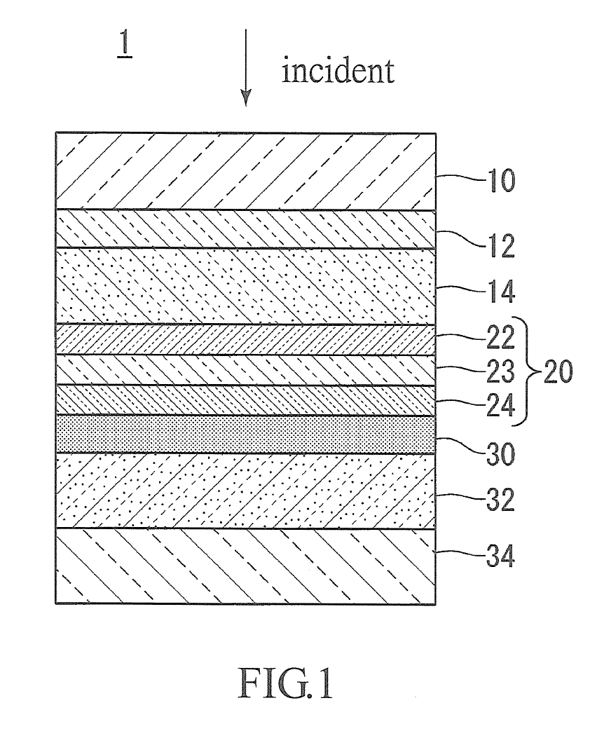

Embodiments of a power generation battery of the invention are described hereinafter with reference to the figures.

[First Embodiment] FIG. 1 is a diagram showing an example of the configuration of a power generation battery 1. In the power generation battery 1, a substrate 10, a transparent electrode 12, a first photoelectric conversion layer 14, an intermediate layer 20, a visible light cut filter 30, a second photoelectric conversion layer 32, and an electrode 34 are laminated in this order from a light incident side.

The substrate 10 is formed of transparent glass, resin, or the like, for example, in the form of a plate or a sheet. Moreover, the substrate 10 is composed of an insulating material, for example. The transparent electrode 12 is a transparent or highly light transmissive electrode. The transparent electrode 12 is formed of a conductive oxide, such as a transparent electrode layer (ITO film), for example. The electrode 34 is formed of a material that has high conductivity. The electrode 34 is a transparent or highly light transmissive electrode. For example, the electrode 34 may be formed of Al (aluminum), Ca (calcium), Mg (magnesium), Ag (silver), Cu (copper), Pt (platinum) . . . etc.

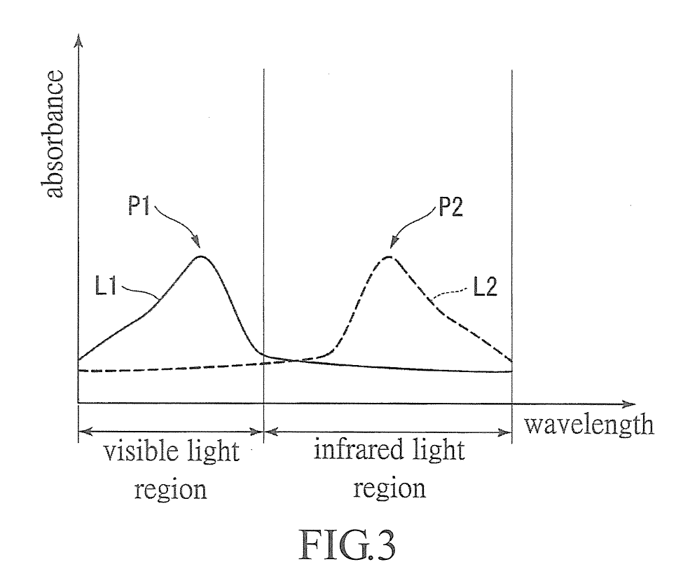

The first photoelectric conversion layer 14 absorbs a visible light (energy of light) of an incident light to generate electric power. The first photoelectric conversion layer 14 includes a semiconductor that has a main absorption region in a visible light region. Having the main absorption region in the visible light region means that there exists an apex of light absorption in the visible light region and/or an integrated value of the absorbance of the visible light region is greater than an integrated value of the absorbance of a region different from visible light (details will be described with reference to FIG. 3). The first photoelectric conversion layer 14 is transparent or light transmissive, for example.

π-conjugated polymers are preferable as an organic semiconductor that has the main absorption region in the visible light region, and those having polyparaphenylenevinylene, polythiophene, polyfluorene, polyaniline, etc., in the main skeleton are preferable in terms of hole conductivity. Examples of such semiconductors may include phthalocyanine pigments, indigo, thioindigo pigments, quinacridone pigments, merocyanine compounds, cyanine compounds, squarylium compounds, or charge transfer agents used in organic electrophotographic photoreceptors, electrically conductive organic charge transfer complexes, etc., and further include conductive polymers.

For example, the first photoelectric conversion layer 14 is formed to combine an organic semiconductor with an n-type semiconductor such that the n-type semiconductor and the organic semiconductor are in contact in the second photoelectric conversion layer 32. Moreover, the semiconductor that has the main absorption region in the visible light region may have a p-n laminated structure which is formed by laminating a layer containing the organic semiconductor (p layer) and a layer containing the n-type semiconductor (n layer), a bulk-heterostructure which is formed by mixing the organic semiconductor and the n-type semiconductor, a p-i-n structure in which a mixture layer formed by mixing the organic semiconductor and the n-type semiconductor by co-vapor deposition, etc., or a composite layer formed by alternately laminating thin films composed of the organic semiconductor and thin films composed of the n-type semiconductor is interposed between the p layer and the n layer as an i layer, or the like, for example. With such a configuration, the performance of the power generation battery 1 can be enhanced.

An appropriate method can be adopted for laminating each of the aforementioned layers. For example, they can be sequentially formed into thin films by a vacuum vapor deposition method, a sputtering method, an ion plating method, a spin coating method, a printing method, etc.

In the intermediate layer 20, a first intermediate electrode 22, an intermediate substrate 23, and a second intermediate electrode 24 are laminated in this order from the light incident side.

The first intermediate electrode 22 is a transparent or highly light transmissive electrode. The first intermediate electrode 22 functions with a polarity that is different from a polarity of the transparent electrode 12. For example, when the transparent electrode 12 is positive, the first intermediate electrode 22 functions as negative. The first intermediate electrode 22 is formed of a conductive oxide, such as a transparent electrode layer (ITO film), for example. The first intermediate electrode 22 is formed of a material that has high conductivity. The electrode 34 may be formed of Al, Ca, Mg, Ag, Cu, Pt, etc., for example.

The intermediate substrate 23 is formed of transparent glass, resin, or the like, for example, in the form of a plate or a sheet. Moreover, the intermediate substrate 23 is composed of an insulating material, for example.

The second intermediate electrode 24 is a transparent or highly light transmissive electrode. The second intermediate electrode 24 functions with a polarity that is different from the polarity of the electrode 34. For example, when the electrode 34 is negative, the second intermediate electrode 24 functions as positive. The second intermediate electrode 24 is formed of a conductive oxide, such as a transparent electrode layer (ITO film), for example. The second intermediate electrode 24 is formed of a material that has high conductivity. The electrode 34 is formed of Al, Ca, Mg, Ag, Cu, Pt, etc., for example.

The visible light cut filter 30 is disposed on a side of the intermediate layer 20, which is opposite to the side where the light is incident, for example. The visible light cut filter 30 blocks or absorbs light in the visible light region. The visible light cut filter 30 blocks or absorbs light that has a wavelength of 1000 nm or less, for example. The visible light cut filter 30 supplies holes sent from the second photoelectric conversion layer 32 to the second intermediate electrode 24. Nevertheless, the visible light cut filter 30 may also be disposed on the intermediate layer 20 on the side where the light is incident. In that case, the visible light cut filter 30 supplies electrons sent from the first photoelectric conversion layer 14 to the first intermediate electrode 22.

The second photoelectric conversion layer 32 absorbs an infrared light (energy of the light) of the incident light to generate electric power. The second photoelectric conversion layer 32 includes a semiconductor that has a main absorption region in an infrared light region. The semiconductor that has the main absorption region in the infrared light region refers to that an apex of light absorption falls in the infrared light region and/or an integrated value of the absorbance of the infrared light region is greater than an integrated value of the absorbance of a region different from infrared light (details will be described with reference to FIG. 3). The second photoelectric conversion layer 32 is transparent or light transmissive, for example.

π-conjugated polymers are preferable as the semiconductor that has the main absorption region in the infrared light region, and those having polyparaphenylenevinylene, polythiophene, polyfluorene, polyaniline, etc., in the main skeleton are preferable in terms of hole conductivity. However, it is particularly preferable to use those that have a huge π-conjugated system to increase absorption in the long wavelength region.

Examples of the semiconductor that has the main absorption region in the infrared light region may include naphthalocyanine or a naphthalocyanine derivative. A central metal of the naphthalocyanine or the naphthalocyanine derivative may be various metals, such as Cu (copper), Zn (zinc), Ti (titanium), Ni (nickel), Fe (iron), etc.

For example, the second photoelectric conversion layer 32 is formed to combine an organic semiconductor with an n-type semiconductor such that the n-type semiconductor and the organic semiconductor are in contact in the second photoelectric conversion layer 32. For example, through formation of a p-n laminated structure which is formed by laminating a layer containing the organic semiconductor (p layer) and a layer containing the n-type semiconductor (n layer), a bulk-heterostructure which is formed by mixing the organic semiconductor and the n-type semiconductor, a p-i-n structure in which a mixture layer formed by mixing the organic semiconductor and the n-type semiconductor by co-vapor deposition, etc., or a composite layer formed by alternately laminating thin films composed of the organic semiconductor and thin films composed of the n-type semiconductor is interposed between the p layer and the n layer as an i layer, or the like, the performance of the power generation battery 1 can be enhanced.

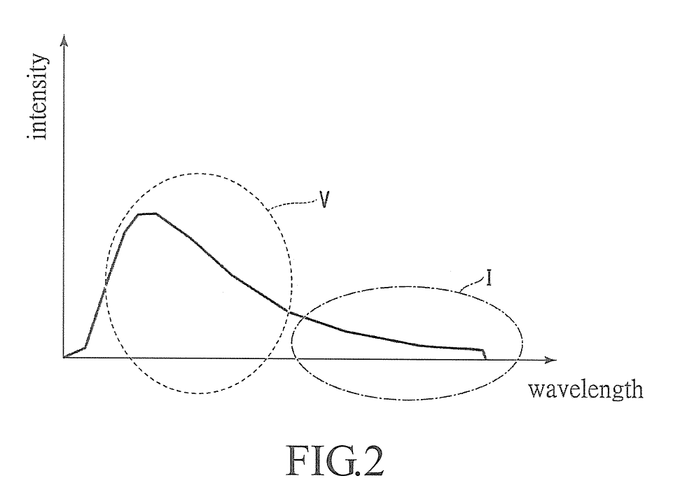

FIG. 2 is a diagram for illustrating the wavelengths absorbed by the first photoelectric conversion layer 14 and the second photoelectric conversion layer 32. In the figure, the vertical axis indicates the intensity (radiation energy) while the horizontal axis indicates the wavelength. The first photoelectric conversion layer 14 absorbs a visible light region V that includes a wavelength of less than 1000 nm, for example. The second photoelectric conversion layer 32 absorbs an infrared light region I that includes a wavelength of 1000 nm or more, for example.

FIG. 3 is a diagram for illustrating the apex of light absorption and the integrated value of absorbance. In the figure, the vertical axis indicates the absorbance while the horizontal axis indicates the wavelength. The example shown in the figure illustrates a region where the wavelength is a visible light and a region where the wavelength is an infrared light. A transition line L1 represents the light absorbed by the first photoelectric conversion layer 14. A transition line L2 represents the light absorbed by the second photoelectric conversion layer 32. Regarding the first photoelectric conversion layer 14, an apex P1 of light absorption falls in the visible light region, and the integrated value of the absorbance of the visible light region is greater than the integrated value of the absorbance of the region (the infrared light region) different from visible light. Regarding the second photoelectric conversion layer 32, an apex P2 of light absorption falls in the infrared light region, and the integrated value of the absorbance of the infrared light region is greater than the integrated value of the absorbance of the region (the visible light region) different from the infrared light region.

Here, in the case of generating electric power with use of a power generation battery, in which the substrate 10, the transparent electrode 12, the second photoelectric conversion layer 32 having the main absorption region in the infrared light region, the intermediate layer 20, the first photoelectric conversion layer 14 having the main absorption region in the visible light region, and the electrode 34 are laminated in this order from the light incident side without the visible light cut filter 30, when light reaches the first photoelectric conversion layer 14, light in the visible light region where the power generation efficiency is high is attenuated. Therefore, power generation in the first photoelectric conversion layer 14 may not be performed efficiently. Moreover, when electric power is generated by using a power generation battery, in which the substrate 10, the transparent electrode 12, the first photoelectric conversion layer 14 having the main absorption region in the visible light region, the intermediate layer 20, the second photoelectric conversion layer 32 having the main absorption region in the infrared light region, and the electrode 34 are laminated in this order from the light incident side without the visible light cut filter 30, the power generation efficiency may decrease. The reason is that, in such a case, the visible light that cannot be absorbed by the first photoelectric conversion layer 14 reaches the second photoelectric conversion layer 32 and causes the second photoelectric conversion layer 32 to generate heat.

In contrast thereto, the power generation battery 1 of this embodiment includes the substrate 10, the transparent electrode 12, the first photoelectric conversion layer 14 having the main absorption region in the visible light region, the intermediate layer 20, the second photoelectric conversion layer 32 having the main absorption region in the infrared light region, and the electrode 34 that are laminated in this order from the light incident side. Accordingly, light in the visible light region reaches the first photoelectric conversion layer 14 without being attenuated, as described above, and therefore power generation can be efficiently performed in the first photoelectric conversion layer 14. In addition, the visible light that cannot be absorbed by the first photoelectric conversion layer 14 is blocked or absorbed by the visible light cut filter 30. Thus, heat generated by the second photoelectric conversion layer 32 due to receipt of the visible light can be suppressed. As a result, the power generation efficiency of the power generation battery 1 is improved.

Further, since the heat generated by the second photoelectric conversion layer 32 due to receipt of the visible light can be suppressed by the visible light cut filter 30, when the power generation battery 1 is used in a region of long daytime or a region of a large amount of solar radiation, deterioration of the power generation battery 1 can be suppressed. Consequently, the life of the power generation battery 1 can be prolonged.

In this embodiment, one or both of the first photoelectric conversion layer 14 and the second photoelectric conversion layer 32 may be single crystal silicon semiconductors or polycrystalline silicon semiconductors, thin film silicon semiconductors, GIGS semiconductors, dye sensitized semiconductors, etc.

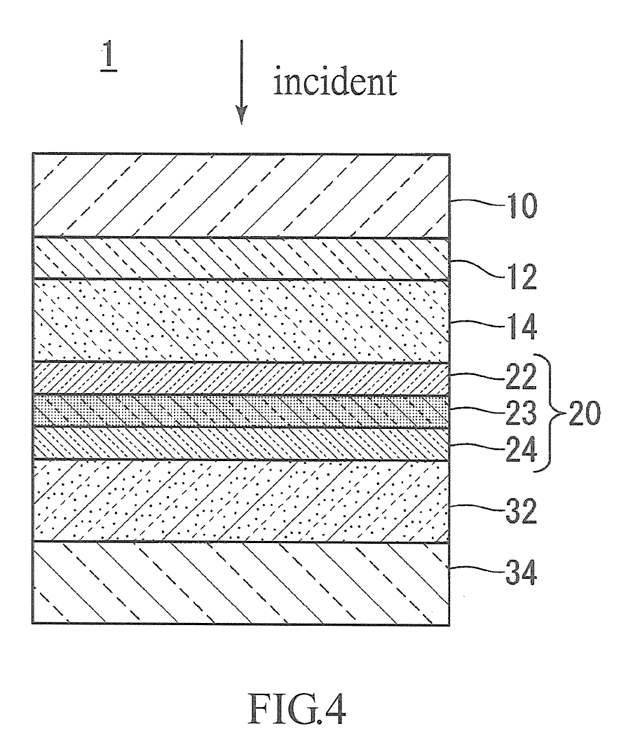

Besides, in the power generation battery 1, lamination of the visible light cut filter 30 may be omitted, and one or more of the first intermediate electrode 22, the intermediate substrate 23, and the second intermediate electrode 24 may have the function of blocking or absorbing light in the visible light region, same as the visible light cut filter 30. In that case, the first intermediate electrode 22, the intermediate substrate 23, and/or the second intermediate electrode 24 for blocking or absorbing light in the visible light region is a “filter layer.” FIG. 4 is a diagram showing an example where lamination of the visible light cut filter 30 is omitted.

The power generation battery 1 of the first embodiment as described above includes the first photoelectric conversion layer 14 which has the apex of light absorption in the visible light region and absorbs light to generate electric power, the second photoelectric conversion layer 32 which is disposed on the side opposite to the incident direction side of the first photoelectric conversion layer 14 and has the apex of light absorption in the infrared light region and absorbs light to generate electric power, and the visible light cut filter 30 which blocks or absorbs light in the visible light region between the first photoelectric conversion layer 14 and the second photoelectric conversion layer 32, by which the power generation efficiency is improved.

[Second Embodiment] The second embodiment is described hereinafter. In the power generation battery 1 of the first embodiment, the intermediate layer 20 is provided with electrodes. In contrast thereto, a power generation battery 1A of the second embodiment recombines the electrons sent from the first photoelectric conversion layer 14 and the holes sent from the second photoelectric conversion layer 32 in an intermediate layer 20A. The following focuses on the difference between the second embodiment and the first embodiment.

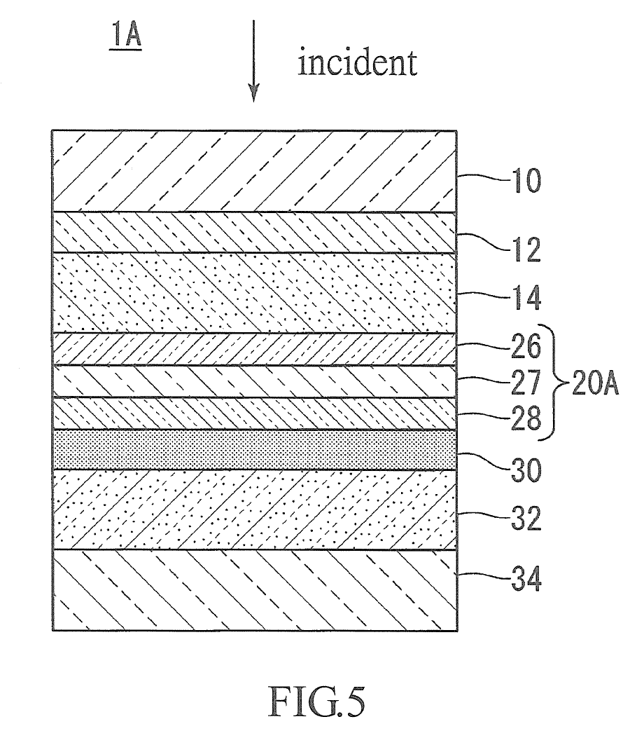

FIG. 5 is a diagram showing an example of the configuration of the power generation battery 1A. In the power generation battery 1A, the substrate 10, the transparent electrode 12, the first photoelectric conversion layer 14, the intermediate layer 20A, the visible light cut filter 30, the second photoelectric conversion layer 32, and the electrode 34 are laminated in this order from the light incident side.

The intermediate layer 20A of the second embodiment is a carrier recombination layer that combines the electrons and holes respectively supplied from the first photoelectric conversion layer 14 and the second photoelectric conversion layer 32 to conduct the first photoelectric conversion layer 14 and the second photoelectric conversion layer 32. In the intermediate layer 20A, an electron transport layer 26, a transparent layer 27, and a hole transport layer 28 are laminated in this order from the light incident side.

The electron transport layer 26 is formed of a lithium fluoride layer that contains lithium fluoride, for example. The lithium fluoride layer is formed of a vapor deposition film of lithium fluoride (LiF), etc., for example. The thickness of the lithium fluoride layer is preferably 0.1 nm to 0.5 nm. The reason is that if the thickness of the lithium fluoride layer is greater than 0.5 nm, the photoelectric conversion efficiency may drop. The electron transport layer 26 also functions as a layer for transport of electrons in the first photoelectric conversion layer 14 adjacent to the intermediate layer 20A. The electron transport layer 26 may be a part of the first photoelectric conversion layer 14.

In addition, the electron transport layer 26 may be a layer containing Ag and Mg. In that case, it may be a layer (mixture layer) of mixture of Ag and Mg, or an AgMg laminated film in which Ag and Mg are sequentially laminated. In the case where the electron transport layer 26 is formed of the AgMg laminated film, Ag may be laminated on the side of the first photoelectric conversion layer 14 and Mg may be laminated on the side of the transparent layer 27, or Mg may be laminated on the side of the second photoelectric conversion layer 32 and Ag may be laminated on the side of the transparent layer 27. The layer containing Ag and Mg can be formed by vapor deposition, and can be formed by co-vapor deposition in the case of the mixture layer. If the electron transport layer 26 is formed of the aforementioned material, the electron transport layer 26 can achieve the function of transporting electrons even with a very small film thickness and can form a favorable interface.

The hole transport layer 28 is formed of a molybdenum oxide layer containing molybdenum oxide, for example. The molybdenum oxide layer is formed of a vapor deposited film of molybdenum oxide (MₒOₓ; X=2 to 4), etc., for example. Moreover, the thickness of the molybdenum oxide layer is preferably 3 nm to 20 nm. Thereby, the hole transporting property and light transmittance can both be achieved. The hole transport layer 28 also functions as a layer for transport of holes in the second photoelectric conversion layer 32 adjacent to the intermediate layer 20A. The hole transport layer 28 may be a part of the first photoelectric conversion layer 14.

Here, it is also possible to use PEDOT: PSS (applied and formed by water solubility), i.e., typical hole transport layer, as the hole transport layer 28, for example. However, the aforementioned molybdenum oxide is preferable. Because moisture is imparted to the organic layers, e.g., the second photoelectric conversion layer 32, and annealing at 100° C. or higher is required, the underlying organic layers may be damaged. When the hole transport layer 28 is particularly formed of the molybdenum oxide, the hole transport layer 28 has excellent hole transporting property and light transmittance and does not easily cause damage to the second photoelectric conversion layer 32, etc. that serves as the base, and furthermore, has the characteristic of high stability against sunlight.

The transparent layer 27 is a transparent oxide layer with conductivity or a transparent nitride layer. This layer is formed of a metal oxide or metal nitride material that is used as a transparent electrode, for example. Specifically, this layer is formed of a transparent electrode material of an oxide or nitride, such as indium tin oxide (ITO), In2O3ZnO (IZO), Ga2O3ZnO (GZO), Al doped ZnO (AZO), etc. In the case of using the aforementioned materials, the transparent layer 27 can be formed by a sputtering method, a vapor deposition method, etc.

The thickness of the transparent layer 27 is preferably 150 nm or less. Thereby, the probability of recombination of the electrons and holes can be increased. The reason is that if the thickness of the transparent layer 27 exceeds this range, the electric resistance component increases and results in deterioration of the solar cell characteristics. In addition, the thickness of the transparent layer 27 is preferably 10 nm or more. If the transparent layer 27 is thinner than this range, when a blend material is applied to form the layers of the power generation battery 1, the solvent may penetrate into the layers of the power generation battery 1 that have already been formed.

The transparent layer 27 is the region where the electrons sent from the electron transport layer 26 and the holes sent from the hole transport layer 28 are recombined and functions as a recombination layer. When the intermediate layer 20A is formed, among the electrons and holes generated in the first photoelectric conversion layer 14 adjacent to the intermediate layer 20A, mainly the electrons are sent to the transparent layer 27 via the electron transport layer 26. In addition, among the electrons and holes generated in the second photoelectric conversion layer 32, mainly the holes are sent to the transparent layer 27 via the hole transport layer 28. Thus, although the electron transport layer 26 and the hole transport layer 28 themselves do not receive light to generate carriers, they supply electrons and holes to the transparent layer 27 in a well-balanced manner. Then, the electrons and holes are recombined in the transparent layer 27 that functions as the recombination layer. At the moment, if the first photoelectric conversion layer 14 and the second photoelectric conversion layer 32 are designed to have equal carrier generation amounts, the numbers of the electrons and holes injected into the recombination layer are the same due to the blocking effect of the electron transport layer 26 and the hole transport layer 28, and the recombination is carried out in a well-balanced manner without an excess of any of the carriers. Particularly, if the transparent layer 27 is formed of a highly conductive material such as ITO, due to the high conductivity, the recombination is carried out efficiently.

The transparent electrode 12 of the second embodiment functions with a polarity that is different from the polarity of the electrode 34. For example, when the electrode 34 is positive, the transparent electrode 12 functions as negative.

Furthermore, in the power generation battery 1A, the visible light cut filter 30 may be laminated between the first photoelectric conversion layer 14 and the intermediate layer 20A, instead of being laminated between the intermediate layer 20 and the second photoelectric conversion layer 32. In that case, the visible light cut filter 30 supplies the electrons sent from the first photoelectric conversion layer 14 to the electron transport layer 26.

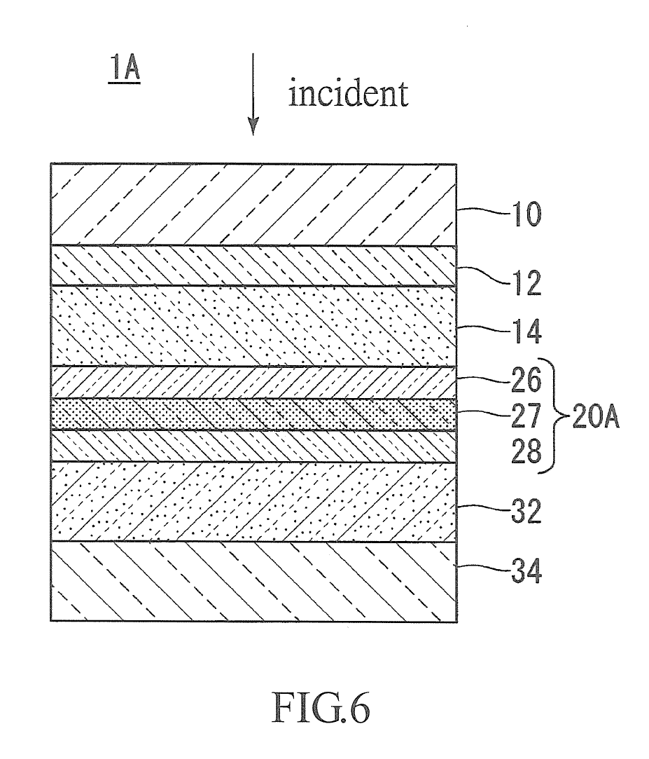

Besides, in the power generation battery 1A, lamination of the visible light cut filter 30 may be omitted, and one or more of the electron transport layer 26, the transparent layer 27, and the hole transport layer 28 may have the function of blocking or absorbing light in the visible light region, same as the visible light cut filter 30. In that case, the electron transport layer 26, the transparent layer 27, and/or the hole transport layer 28 for blocking or absorbing light in the visible light region is a “filter layer.” FIG. 6 is a diagram showing an example where lamination of the visible light cut filter 30 is omitted.

The power generation battery 1A of the second embodiment as described above achieves the same effect as the first embodiment and can improve the power generation efficiency.

[Third Embodiment] The third embodiment is described hereinafter. The third embodiment relates to a vehicle M, which utilizes a power generation battery module 100 configured by arranging a plurality of the power generation batteries 1 and 1A. The following focuses on the difference between the third embodiment and the first and second embodiments.

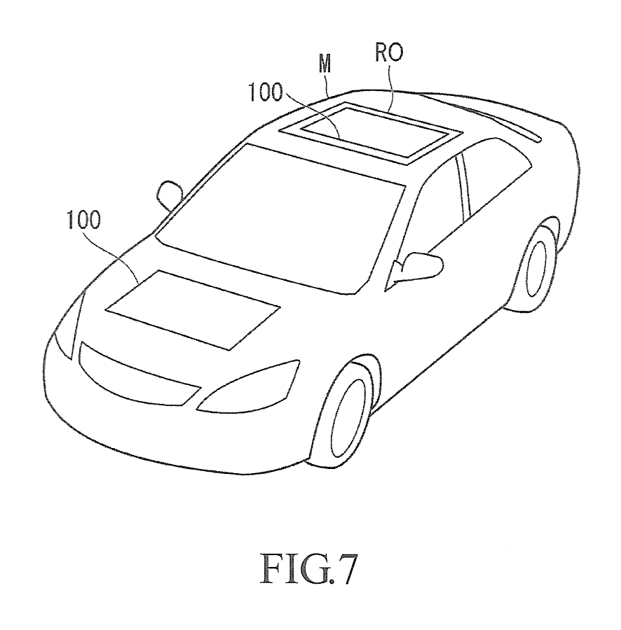

FIG. 7 illustrates an example of the vehicle M, which utilizes the power generation battery module 100 configured by arranging a plurality of the power generation batteries 1 and 1A. The power generation battery module 100 is disposed at a position of the vehicle M to be irradiated by light. The power generation battery module 100 is disposed on the outer side of a bonnet or on a roof of the vehicle M, for example. Moreover, the power generation battery module 100 may be disposed on a sunroof RO of the vehicle M, for example. For example, if the sunroof RO is formed of glass, the power generation battery module 100 may be formed integrally with the glass.

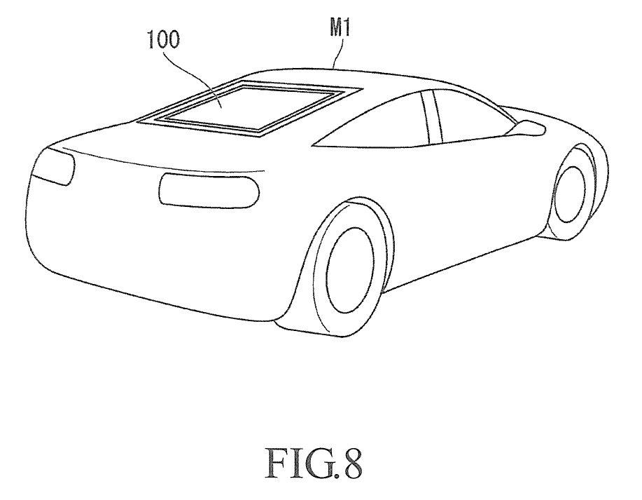

In addition, the power generation battery module 100 may be disposed in a vehicle rear part (near a rear window, for example) of a vehicle M1, or be disposed as a part of the rear window, for example. Moreover, the power generation battery module 100 may be disposed in place of the rear window of the vehicle M1. FIG. 8 is a diagram showing an example of the vehicle M1, in which the power generation battery module 100 is disposed in place of the rear window of the vehicle M1. In that case, the vehicle M1 may include a display instead of a rearview mirror. An image captured by a rear camera that images the rear view of the vehicle M1 (in the direction toward the rear of the vehicle) is displayed on the display. The image captured by the rear camera corresponds to a scene, which an occupant can visually recognize through the rearview minor when the power generation battery module 100 is not disposed in place of the rear window. Thereby, the occupant is able to learn the situation behind the vehicle through the image displayed on the display. Thus, by disposing the power generation battery module 100 in the rear part of the vehicle M1, the space of the vehicle M1 can be used effectively to achieve efficient power generation while desired visibility for the rear of the vehicle is secured.

The vehicle M that uses the power generation battery module 100 of the third embodiment as described above achieves the same effect as the first embodiment, and the electric power generated by the power generation battery module 100 can be supplied to a storage battery, an internal combustion engine (engine), a motor, etc., of the vehicle M. Further, in the case that there is much noise in the vehicle M, for example, if the visible light cut filter 30 has conductivity, the noise in the vehicle M can be shielded.

Several embodiments of the invention have been described above. However, the invention should not be construed as being limited to these embodiments, and various modifications and substitutions may be made without departing from the scope of the invention.

What is claimed is:

1. A power generation battery, comprising:
a first layer comprising a semiconductor element that has a main absorption region in a visible light region and absorbs light to generate electric power;
a second layer disposed on a side opposite to an incident direction side of the first layer, and the second layer comprising a semiconductor element that has a main absorption region in an infrared light region and absorbs light to generate electric power; and
a filter layer disposed between the first layer and the second layer and blocking or absorbing a light in the visible light region.

2. The power generation battery according to claim 1, further comprising an intermediate layer between the first layer and the second layer, in addition to the filter layer, wherein the intermediate layer comprises an first electrode that conducts with the first layer and an second electrode that conducts with the second layer.

3. The power generation battery according to claim 1, further comprising an intermediate layer between the first layer and the second layer, in addition to the filter layer, wherein the intermediate layer combines electrons supplied from one of the first layer and the second layer with holes supplied from the other one of the first layer and the second layer.

4. The power generation battery according to claim 1, wherein the filter layer is an intermediate layer which blocks or absorbs light in the visible light region and comprises an first electrode that conducts with the first layer and an second electrode that conducts with the second layer, or an intermediate layer which blocks or absorbs light the visible light region and combines electrons supplied from one of the first layer and the second layer with holes supplied from the other one of the first layer and the second layer.
